(19) United States
(12) Patent Application Publication
(10) Pub. No.: US 2013/0015500 A1
(43) Pub. Date: Jan. 17, 2013

(54) SEMICONDUCTOR DEVICE

(71) Applicants: Takashi IZUMIDA, Kanagawa (JP); Toshitaka MIYATA, Kanagawa (JP)

(72) Inventors: Takashi IZUMIDA, Kanagawa (JP); Toshitaka MIYATA, Kanagawa (JP)

(73) Assignee: Kabushiki Kaisha Toshiba, Tokyo (JP)

(21) Appl. No.: 13/410,697

(22) Filed: Mar. 2, 2012

(30) Foreign Application Priority Data
Jul. 14, 2011 (JP) 2011-155854

(51) Int. Cl. H01L 29/78

(52) U.S. Cl. 257/192; 257/E29.255

(57) ABSTRACT

According to one embodiment, a semiconductor device includes a semiconductor protrusion formed on a semiconductor substrate, a source/drain layer provided in a vertical direction of the semiconductor protrusion, a gate electrode provided on a side surface of the semiconductor protrusion through a gate insulating film, and a channel region provided on the side surface of the semiconductor protrusion. The potential height in the channel region is different between the drain layer side and the source layer side.

### CROSS-REFERENCE TO RELATED APPLICATIONS

This application is based upon and claims the benefit of priority from Japanese Patent Application No. 2011-155854, filed on Jul. 14, 2011; the entire contents of which are incorporated herein by reference.

### FIELD

Embodiments described herein relate generally to a semiconductor device.

### BACKGROUND

In a field-effect transistor, potential controllability in a channel region according to a gate electrode is lowered with the miniaturization of the field-effect transistor, and a short channel effect becomes prominent, so that it is difficult to simultaneously realize reduction of the short channel effect and increase of a current drive force.

Meanwhile, in a fin-type transistor, since gate electrodes are provided on the both sides of the channel region, the potential controllability in the channel region is improved, and it is effective in simultaneously realizing the reduction of the short channel effect and the increase of the current drive force.

### BRIEF DESCRIPTION OF THE DRAWINGS

FIG. 1A is a plan view illustrating a schematic configuration of a semiconductor device according to a first embodiment; FIG. 1B is a cross-sectional view illustrating the schematic configuration of the semiconductor device according to the first embodiment; FIG. 1C is a cross-sectional view illustrating another example of the schematic configuration of the semiconductor device according to the first embodiment; FIG. 1D is a view illustrating a potential of a channel region along a vertical direction of a semiconductor protrusion 2 of the semiconductor device according to the first embodiment;

FIG. 2A is a plan view illustrating a method of manufacturing a semiconductor device according to a second embodiment; FIG. 2B is a cross-sectional view illustrating the method of manufacturing the semiconductor device according to the second embodiment;

FIG. 3A is a plan view illustrating the method of manufacturing the semiconductor device according to the second embodiment; FIG. 3B is a cross-sectional view illustrating the method of manufacturing the semiconductor device according to the second embodiment;

FIG. 4A is a plan view illustrating the method of manufacturing the semiconductor device according to the second embodiment; FIG. 4B is a cross-sectional view illustrating the method of manufacturing the semiconductor device according to the second embodiment;

FIG. 5A is a plan view illustrating the method of manufacturing the semiconductor device according to the second embodiment; FIG. 5B is a cross-sectional view illustrating the method of manufacturing the semiconductor device according to the second embodiment;

FIG. 6A is a plan view illustrating the method of manufacturing the semiconductor device according to the second embodiment; FIG. 6B is a cross-sectional view illustrating the method of manufacturing the semiconductor device according to the second embodiment;

FIG. 7A is a plan view illustrating the method of manufacturing the semiconductor device according to the second embodiment; FIG. 7B is a cross-sectional view illustrating the method of manufacturing the semiconductor device according to the second embodiment;

FIG. 8A is a plan view illustrating the method of manufacturing the semiconductor device according to the second embodiment; FIG. 8B is a cross-sectional view illustrating the method of manufacturing the semiconductor device according to the second embodiment;

FIG. 9A is a plan view illustrating a method of manufacturing a semiconductor device according to a third embodiment; FIG. 9B is a cross-sectional view illustrating the method of manufacturing the semiconductor device according to the third embodiment;

FIG. 10A is a plan view illustrating the method of manufacturing the semiconductor device according to the third embodiment; FIG. 10B is a cross-sectional view illustrating the method of manufacturing the semiconductor device according to the third embodiment;

FIG. 11A is a plan view illustrating the method of manufacturing the semiconductor device according to the third embodiment; FIG. 11B is a cross-sectional view illustrating the method of manufacturing the semiconductor device according to the third embodiment;

FIG. 12A is a plan view illustrating the method of manufacturing the semiconductor device according to the third embodiment; FIG. 12B is a cross-sectional view illustrating the method of manufacturing the semiconductor device according to the third embodiment;

FIG. 13A is a plan view illustrating the method of manufacturing the semiconductor device according to the third embodiment; FIG. 13B is a cross-sectional view illustrating the method of manufacturing the semiconductor device according to the third embodiment;

FIG. 14A is a plan view illustrating a schematic configuration of a semiconductor device according to a fourth embodiment; FIG. 14B is a cross-sectional view illustrating the schematic configuration of the semiconductor device according to the fourth embodiment; FIG. 14C is a cross-sectional view illustrating another example of the schematic configuration of the semiconductor device according to the fourth embodiment;

FIG. 15A is a plan view illustrating a method of manufacturing a semiconductor device according to a fifth embodiment; FIG. 15B is a cross-sectional view illustrating the method of manufacturing the semiconductor device according to the fifth embodiment;

FIG. 16A is a plan view illustrating the method of manufacturing the semiconductor device according to the fifth embodiment; FIG. 16B is a cross-sectional view illustrating the method of manufacturing the semiconductor device according to the fifth embodiment;

FIG. 17A is a plan view illustrating the method of manufacturing the semiconductor device according to the fifth embodiment; FIG. 17B is a cross-sectional view illustrating the method of manufacturing the semiconductor device according to the fifth embodiment;

FIG. 18A is a plan view illustrating the method of manufacturing the semiconductor device according to the fifth embodiment; FIG. 18B is a cross-sectional view illustrating the method of manufacturing the semiconductor device according to the fifth embodiment;

FIG. 19A is a plan view illustrating the method of manufacturing the semiconductor device according to the fifth embodiment; FIG. 19B is a cross-sectional view illustrating the method of manufacturing the semiconductor device according to the fifth embodiment;

FIG. 20A is a plan view illustrating the method of manufacturing the semiconductor device according to the fifth embodiment; FIG. 20B is a cross-sectional view illustrating the method of manufacturing the semiconductor device according to the fifth embodiment;

FIG. 21A is a plan view illustrating a schematic configuration of a semiconductor device according to a sixth embodiment; and FIG. 21B is a cross-sectional view illustrating the schematic configuration of the semiconductor device according to the sixth embodiment.

### DETAILED DESCRIPTION

In general, according to a semiconductor device of embodiments, a semiconductor protrusion, a source/drain layer, a gate electrode, and a channel region are provided. The semiconductor protrusion is formed on a semiconductor substrate. The source/drain layer is provided in the vertical direction of the semiconductor protrusion. The gate electrode is provided on the side surface of the semiconductor protrusion through a gate insulating film. The channel region is provided on the side surface of the semiconductor protrusion, and in the region other than a depletion layer formed between the source/drain layer and the semiconductor protrusion, the potential height is different between the drain layer side and the source layer side.

Hereinafter, the semiconductor device according to the embodiments will be described with reference to the drawings. The present invention is not limited to those embodiments.

### First Embodiment

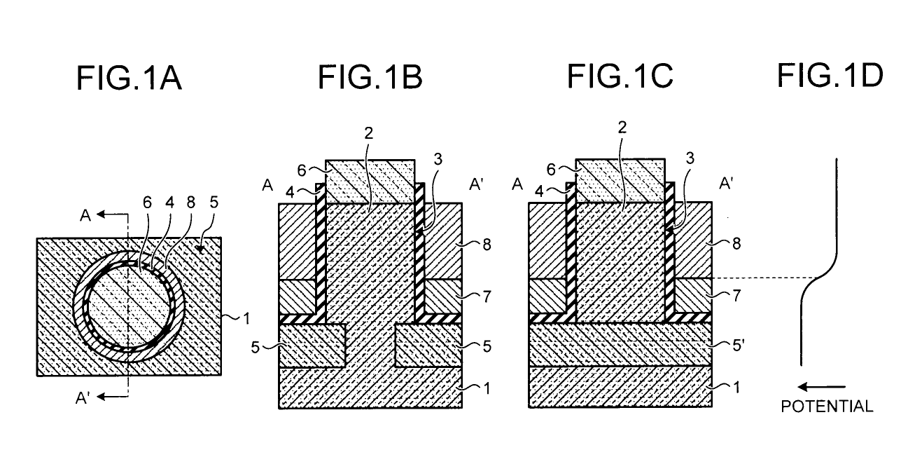

FIG. 1A is a plan view illustrating a schematic configuration of a semiconductor device according to a first embodiment. FIG. 1B is a cross-sectional view illustrating the schematic configuration of the semiconductor device according to the first embodiment. FIG. 1C is a cross-sectional view illustrating another example of the schematic configuration of the semiconductor device according to the first embodiment. FIG. 1D is a view illustrating a potential of a channel region along a vertical direction of a semiconductor protrusion 2 of the semiconductor device according to the first embodiment. FIGS. 1B and 1C are views cut along A-A line of FIG. 1A.

In FIGS. 1A to 1C, a semiconductor protrusion 2 is formed on a semiconductor substrate 1. As the materials of the semiconductor substrate 1 and the semiconductor protrusion 2, there can be selected from among Si, Ge, SiGe, SiC, SiSn, PbS, GaAs, InP, InGaAsP, GaP, GaN, ZnSe, and so on. The semiconductor substrate 1 and the semiconductor protrusion 2 may be formed of the same material or different materials. The semiconductor protrusion 2 may have a columnar shape or a prism shape. Alternatively, the semiconductor protrusion 2 may have a fin-like shape.

When the semiconductor protrusion 2 has a columnar shape, it is possible to be free from the corner formation in the semiconductor protrusion 2, and electric field concentration can be prevented, so that off current of a transistor can be reduced.

A source layer 5 and a drain layer 6 are formed in the vertical direction of the semiconductor protrusion 2. Here, the source layer 5 may be formed on the semiconductor substrate 1 side, and the drain layer 6 may be formed on a top surface side of the semiconductor protrusion 2. Alternatively, the drain layer 6 may be formed on the semiconductor substrate 1 side, and the source layer 5 may be formed on the top surface side of the semiconductor protrusion 2.

As illustrated in FIG. 1B, for example when the source layer 5 is formed on the semiconductor substrate 1 side, the source layer 5 may be provided at a portion of the bottom surface side of the semiconductor protrusion 2. Alternatively, as illustrated in FIG. 1C, a source layer 5′ may be provided on the entire bottom surface side of the semiconductor protrusion 2. When the source layer 5 is provided at a portion of the bottom surface side of the semiconductor protrusion 2, the source layer 5 can be formed in a ring shape on the bottom surface of the semiconductor protrusion 2. Here, when the source layer 5 is provided at a portion of the bottom surface side of the semiconductor protrusion 2, the semiconductor protrusion 2 can be prevented from being electrically separated from the semiconductor substrate 1, and a substrate bias effect can be produced.

In addition, gate electrodes 7 and 8 are formed on the side surface of the semiconductor protrusion 2 through a gate insulating film 4. Here, the gate electrode 7 is arranged on the source layer 5 side, and the gate electrode 8 is arranged on the drain layer 6 side. When the semiconductor protrusion 2 has a columnar shape or a prism shape, the gate electrodes 7 and 8 may be formed so as to surround the periphery of the semiconductor protrusion 2. When the semiconductor protrusion 2 has a fin-like shape, the gate electrodes 7 and 8 may be formed so as to hold the semiconductor protrusion 2 between the gate electrodes 7 and 8. The materials of the gate electrodes 7 and 8 can be selected so that the work functions of the gate electrodes 7 and 8 are different from each other.

A channel region 3 is provided on the side surface of the semiconductor protrusion 2 between the source layer 5 and the drain layer 6. As illustrated in FIG. 1D, in the channel region 3 other than a depletion layer formed between the source layer 5 and the drain layer 6 and the semiconductor protrusion 2, the potential height is different between the source layer 5 and the drain layer 6. At this point, the potential height on the source layer 5 side can be made higher than the potential height on the drain layer 6 side. In order to make the potential height on the source layer 5 higher than the potential height on the drain layer 6 side, the gate electrode 7 can make the work function higher than the gate electrode 8.

As the material of the gate electrode 7, W may be used, for example. As the material of the gate electrode 8, Al may be used, for example. Alternatively, the material of the gate electrode 7 may be selected from among TaN, Ru, TiAlN, and so on, and the material of the gate electrode 8 may be selected from among HfN, NiSi, Mo, TiN, and so on. As the materials of the gate electrodes 7 and 8, a combination of n-type polysilicon and p-type polysilicon may be used, or such a configuration that the impurity concentration of n-type polysilicon or p-type polysilicon is changed may be used. The material of the gate insulating film 4 can be selected from among SiO₂, HfO, HfSiO, HfSᵢON, HfAlO, HfAlSᵢON, La₂O₃, and so on.

In order to suppress variation of electrical characteristics of a field-effect transistor and reduction in the mobility due to variation of the impurity concentration in the channel region 3, it is preferable that the impurity concentration in the channel region 3 is reduced, and the channel region 3 is completely depleted.

The source layer 5 and the drain layer 6 are formed in the vertical direction of the semiconductor protrusion 2, and the gate electrodes 7 and 8 are arranged so as to surround the semiconductor protrusion 2, whereby the potential controllability in the channel region 3 can be improved while preventing punch-through on the semiconductor substrate 1 side, and the reduction of the short channel effect and the increase of the current drive force can be simultaneously realized.

In the source layer 5, the potential height is higher in comparison with the drain layer 6 side, whereby an effective gate length can be reduced while suppressing the short channel effect, and the current drive force can be increased while suppressing increase in off-leakage current.

In the above embodiment, in order to vary the potential height in the channel region 3 between the drain layer 6 side and the source layer 5 side, although the method of varying the work functions of the gate electrodes 7 and 8 from each other has been described, the effective film thickness of the gate insulating film 4 may be different between the drain layer 6 side and the source layer 5 side. In this case, the work functions of the gate electrodes 7 and 8 may be different from each other or the same as each other. As a method of varying the effective film thickness of the gate insulating film 4 between the drain layer 6 side and the source layer 5 side, the film thickness of the gate insulating film 4 may be different therebetween, or the material of the gate insulating film 4 may be different therebetween.

### Second Embodiment

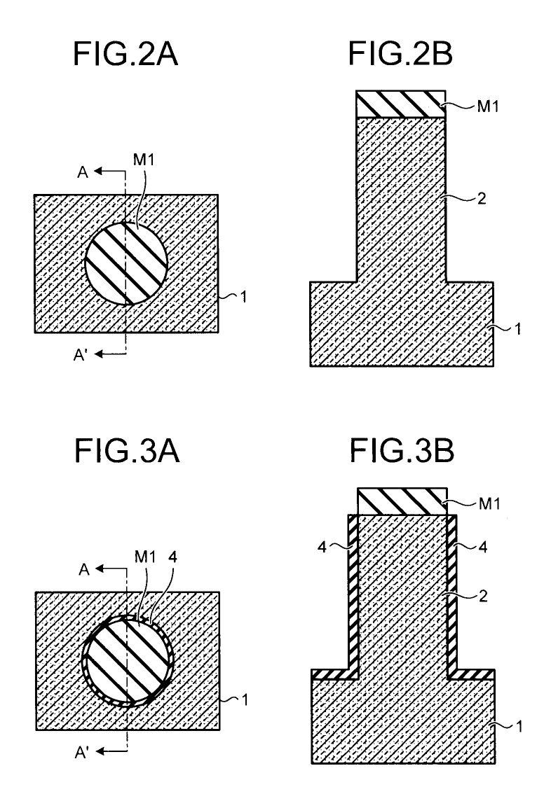

FIGS. 2A to 8A are plan views illustrating a method of manufacturing a semiconductor device according to a second embodiment. FIGS. 2B to 8B are cross-sectional views illustrating the method of manufacturing the semiconductor device according to the second embodiment. FIGS. 2B to 8B are views cut along A-A lines of FIGS. 2A to 8A, respectively.

In FIGS. 2A and 2B, a cap insulating film M1 is film-formed on the entire semiconductor substrate 1 by a CVD method, for example. The cap insulating film M1 on the semiconductor substrate 1 is patterned to be disk-shaped by using a photolithography technique and an etching technique. The cap insulating film M1 can be formed of SiO₂ or SiN, for example. A surface of the semiconductor substrate 1 is etched using the cap insulating film M1 as a mask, whereby a semiconductor protrusion 2 is formed on the semiconductor substrate 1.

Next, as illustrated in FIGS. 3A and 3B, the gate insulating film 4 is formed on the side surface of the semiconductor protrusion 2 by using the CVD method, a thermal oxidation method, or the like.

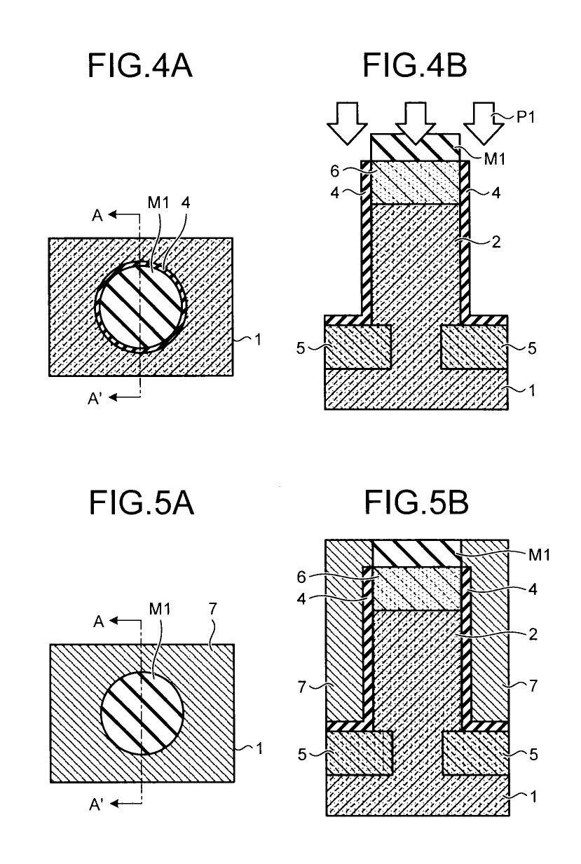

Next, as illustrated in FIGS. 4A and 4B, ion injection P1 is applied to the semiconductor substrate 1 and the semiconductor protrusion 2, whereby the source layer 5 is formed around the semiconductor protrusion 2 on the semiconductor substrate 1 side, and, at the same time, the drain layer 6 is formed on the top surface side of the semiconductor protrusion 2. The injection energy in the ion injection P1 can be set so as not to penetrate through the semiconductor protrusion 2. The semiconductor protrusion 2 is heat-treated after the ion injection P1, whereby the source layer 5 formed around the semiconductor protrusion 2 may be extended outward in the central direction of the semiconductor protrusion 2.

Next, as illustrated in FIGS. 5A and 5B, by using the CVD method, for example, the gate electrode 7 is formed on the semiconductor substrate 1 so that the semiconductor protrusion 2 is embedded. Then, the gate electrode 7 is planarized by a CMP method, for example, until the cap insulating film M1 is exposed. At this time, the cap insulating film M1 can be used as a stopper film in CMP.

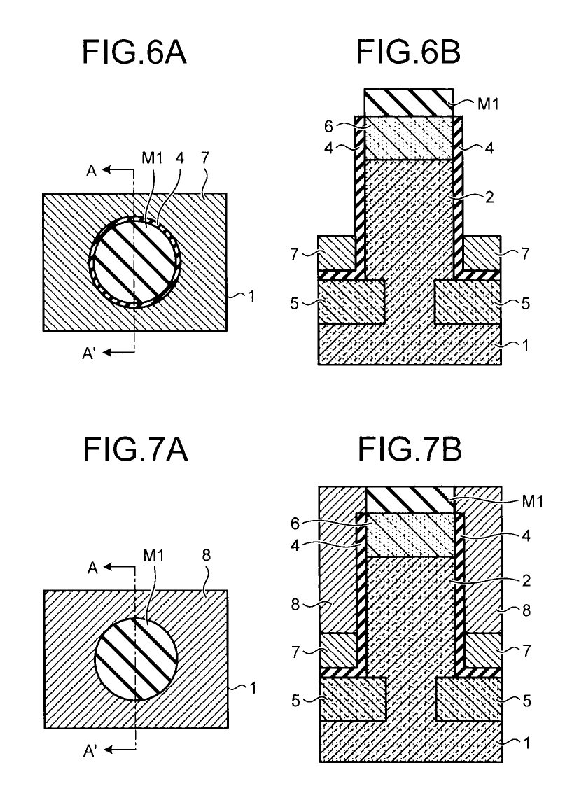

Next, as illustrated in FIGS. 6A and 6B, an upper portion of the gate electrode 7 is removed by etching back the gate electrode 7, and the gate insulating film 4 above the semiconductor protrusion 2 is exposed.

Next, as illustrated in FIGS. 7A and 7B, by using the CVD method, for example, the gate electrode 8 is formed on the gate electrode 7 so that the upper portion of the semiconductor protrusion 2 is embedded. Then, the gate electrode 8 is planarized by the CMP method, for example, until the cap insulating film M1 is exposed. At this time, the cap insulating film M1 can be used as a stopper film in CMP.

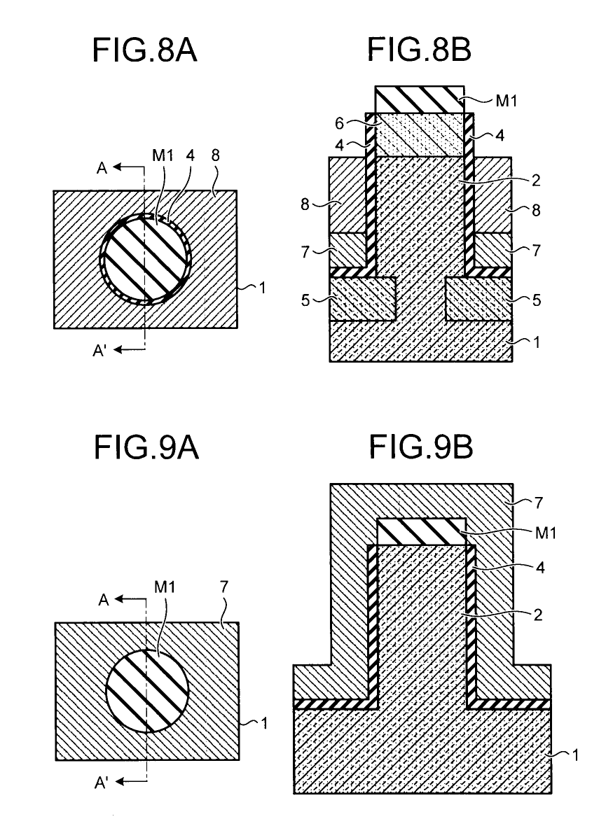

Next, as illustrated in FIGS. 8A and 8B, an upper portion of the gate electrode 8 is removed by etching back the gate electrode 8, and the gate insulating film 4 on the side surface of the drain layer 6 is exposed.

The source layer 5 and the drain layer 6 are formed in the vertical direction of the semiconductor protrusion 2, whereby the gate electrode 8 is stacked on the gate electrode 7, so that the potential height in the channel region 3 can be varied between the drain layer 6 side and the source layer 5 side. Thus, a DWF (Double Work Function) type transistor can be manufactured while suppressing increase of mask processing process in the gate electrodes 7 and 8.

### Third Embodiment

FIGS. 9A to 13A are plan views illustrating a method of manufacturing a semiconductor device according to a third embodiment. FIGS. 9B to 13B are cross-sectional views illustrating the method of manufacturing the semiconductor device according to the third embodiment. FIGS. 9B to 13B are views cut along A-A lines of FIGS. 9A to 13A, respectively.

In FIGS. 9A and 9B, after the process of FIG. 3, by using the CVD method, for example, a gate electrode 7 is formed on a semiconductor substrate 1 so that a semiconductor protrusion 2 is embedded.

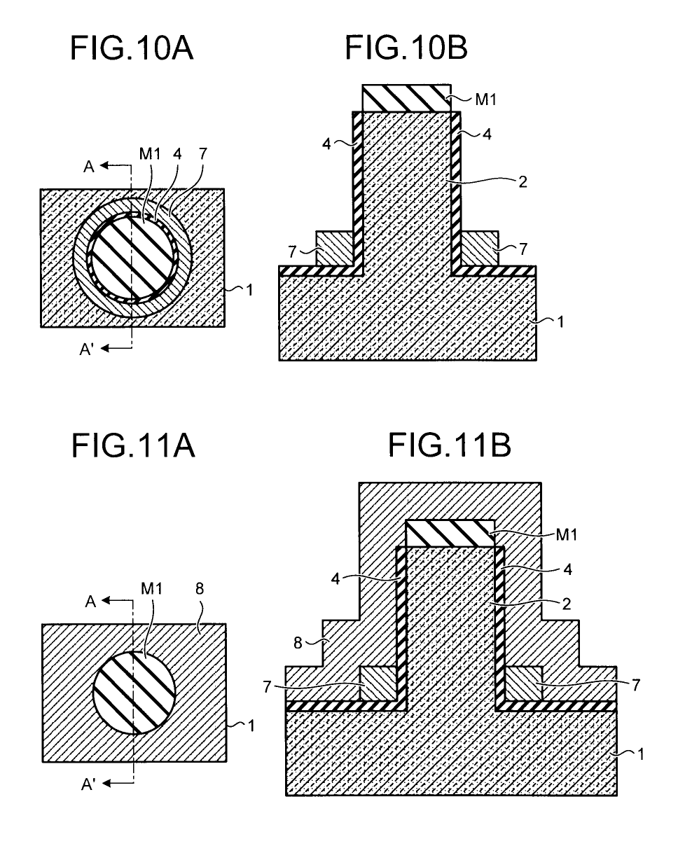

Next, as illustrated in FIGS. 10A and 10B, a gate electrode 7 is etch-backed to be removed except for the gate electrode 7 on the lower side surface of the semiconductor protrusion 2, and a gate insulating film 4 of the upper portion of the semiconductor protrusion 2 is exposed.

Next, as illustrated in FIGS. 11A and 11B, by using a CVD method, for example, the gate electrode 8 is formed on the semiconductor substrate 1 so that the upper portion of the semiconductor protrusion 2 and the gate electrode 7 are embedded.

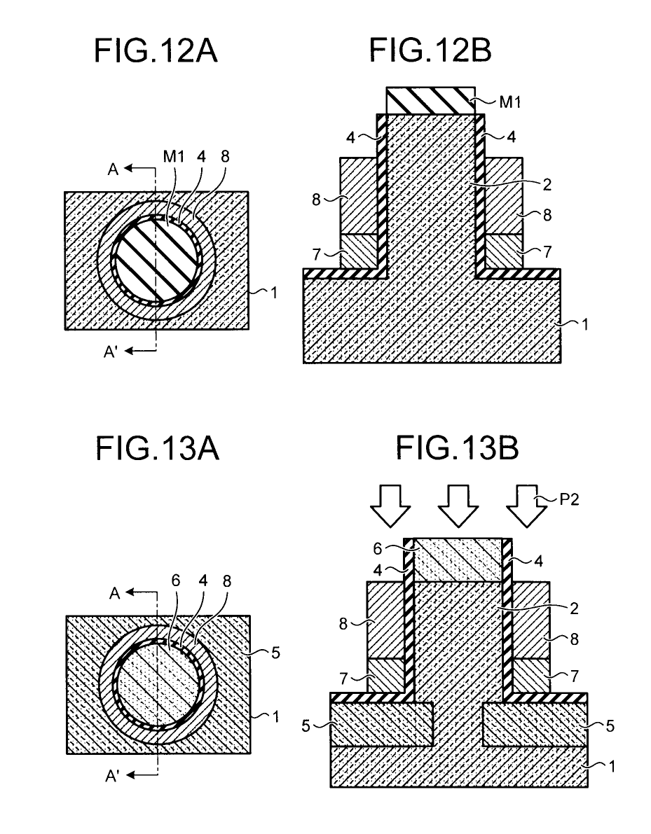

Next, as illustrated in FIGS. 12A and 12B, a gate electrode 8 is etch-backed to be removed except for the gate electrode 8 on the upper side surface of the semiconductor protrusion 2, and the gate insulating film 4 of the upper portion of the semiconductor protrusion 2 is exposed.

Next, as illustrated in FIGS. 13A and 13B, ion injection P2 is applied to the semiconductor substrate 1 and the semiconductor protrusion 2, whereby a source layer 5 is formed around the semiconductor protrusion 2 on the semiconductor substrate 1 side, and, at the same time, a drain layer 6 is formed on the top surface side of the semiconductor protrusion 2.

### Fourth Embodiment

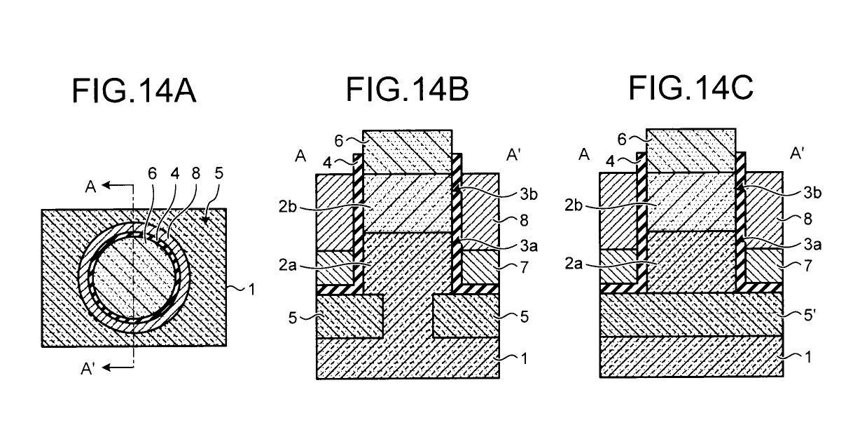

FIG. 14A is a plan view illustrating a schematic configuration of a semiconductor device according to the fourth embodiment. FIG. 14B is a cross-sectional view illustrating the schematic configuration of the semiconductor device according to the fourth embodiment. FIG. 14C is a cross-sectional view illustrating another example of the schematic configuration of the semiconductor device according to the fourth embodiment. FIGS. 14B and 14C are views cut along A-A line of FIG. 14A.

In FIGS. 14A to 14C, the semiconductor device includes semiconductor protrusions 2a and 2b instead of the semiconductor protrusion 2 of FIGS. 1B and 1C. The semiconductor protrusion 2a is formed on a semiconductor substrate 1, and the semiconductor protrusion 2b is formed on the semiconductor protrusion 2a. The semiconductor protrusions 2a and 2b can be configured so that the bandgaps are different from each other. As the materials of the semiconductor protrusions 2a and 2b, there can be selected from among Si, Ge, SiGe, SiC, SiSn, PbS, GaAs, InP, InGaAsP, GaP, GaN, ZnSe, and so on, and Si, SiGe, and a stacked structure can be used, for example. Here, in order to vary the bandgaps of the semiconductor protrusions 2a and 2b from each other, the semiconductor protrusions 2a and 2b may be formed of different materials or have different structures. The semiconductor protrusions 2a and 2b may have a single-crystal structure, a polycrystalline structure, or an amorphous structure, for example.

The side surfaces of the semiconductor protrusions 2a and 2b include channel regions 3a and 3b, respectively. Here, the potential height in the channel region 3a can be made higher than the potential height in the channel region 3b. In order to make the potential height in the channel region 3a higher than the potential height in the channel region 3b, the bandgap of the semiconductor protrusion 2a can be widened in comparison with the semiconductor protrusion 2b.

The semiconductor protrusions 2a and 2b are configured so that the bandgaps are different from each other, whereby the effective gate length can be reduced while suppressing the short channel effect, and the current drive force can be increased while suppressing increase in the off-leakage current.

### Fifth Embodiment

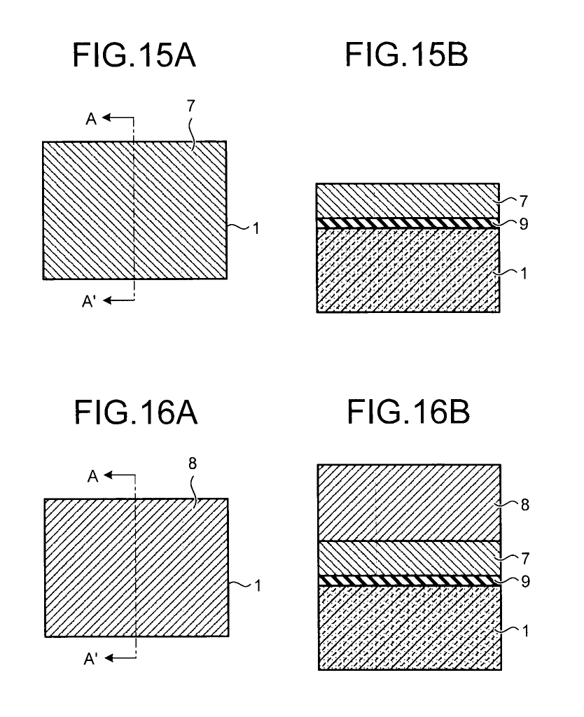

FIGS. 15A to 20A are plan views illustrating a method of manufacturing a semiconductor device according to a fifth embodiment. FIGS. 15B to 20B are cross-sectional views illustrating the method of manufacturing the semiconductor device according to the fifth embodiment. FIGS. 15B to 20B are views cut along A-A lines of FIGS. 15A to 20A, respectively.

In FIGS. 15A and 15B, an insulating film 9 is formed on a semiconductor substrate 1 by using a CVD method, a thermal oxidation method, or the like. Then, a gate electrode 7 is formed on a semiconductor substrate 1 by using the CVD method, for example.

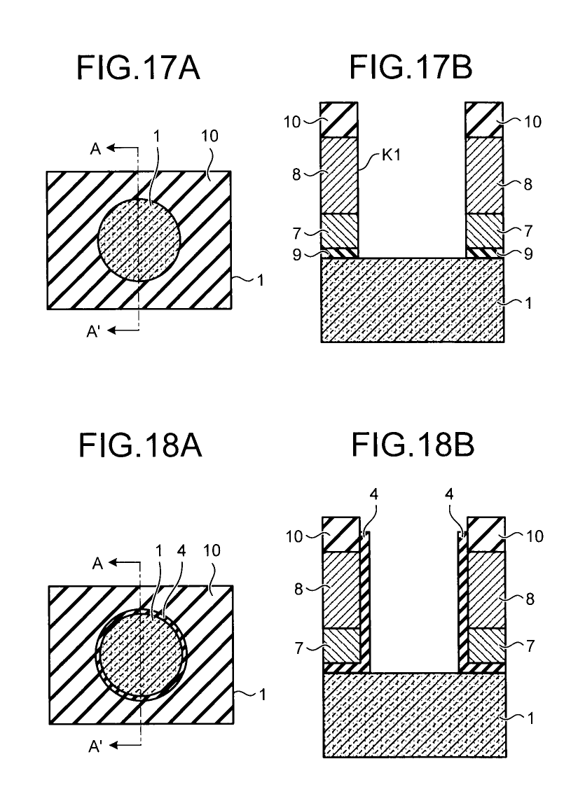

Next, as illustrated in FIGS. 16A to 16B, a gate electrode 8 is formed on the gate electrode 7 by using the CVD method, for example.

Next, as illustrated in FIGS. 17A to 17B, an insulating film 10 is formed on the gate electrode 8 by using the CVD method, for example. Then, an opening K1 is formed in the insulating films 9 and 10 and the gate electrodes 7 and 8 by using a photolithography technique and an etching technique, and a surface of the semiconductor substrate 1 is exposed through the opening K1.

Next, as illustrated in FIGS. 18A and 18B, a gate insulating film 4 is formed on the side surfaces of the gate electrodes 7 and 8 by using the CVD method, the thermal oxidation method, or the like.

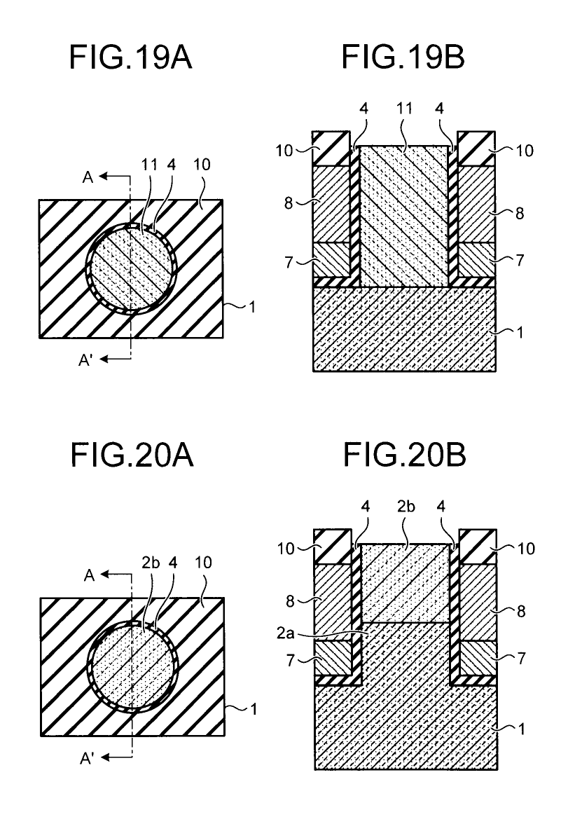

Next, as illustrated in FIGS. 19A and 19B, by using the CVD method, for example, a semiconductor protrusion 11 is embedded in the opening K1, and the semiconductor protrusion 11 is formed on the semiconductor substrate 1. As the semiconductor protrusion 11, an amorphous semiconductor can be used, for example.

Next, as illustrated in FIGS. 20A and 20B, the semiconductor protrusions 11 are heat-treated, whereby the structure of the semiconductor protrusion 11 is changed, and semiconductor protrusions 2a and 2b are formed on the semiconductor substrate 1. As the semiconductor protrusion 2a, a single crystal semiconductor can be used. As the semiconductor protrusion 2b, a polycrystalline semiconductor can be used.

A source layer 5 and a drain layer 6 are formed in the vertical direction of the semiconductor protrusions 2a and 2b, whereby the semiconductor protrusion 2b is stacked on the semiconductor protrusion 2a, so that the potential height can be varied between the channel regions 3a and 3b. Thus, a DWF (Double Work Function) type transistor can be manufactured while suppressing increase of mask processing process in the semiconductor protrusions 2a and 2b.

### Sixth Embodiment

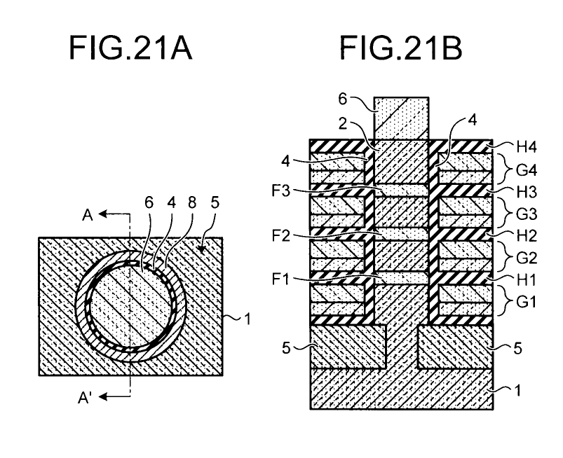

FIG. 21A is a plan view illustrating a schematic configuration of a semiconductor device according to a sixth embodiment. FIG. 21B is a cross-sectional view illustrating the schematic configuration of the semiconductor device according to the sixth embodiment. FIG. 21B is a view cut along A-A line of FIG. 21A.

In FIGS. 21A and 21B, gate electrodes G1 to G4 are formed on a side wall of a semiconductor protrusion 2 through a gate insulating film 4. Here, the gate electrodes G1 to G4 are sequentially stacked through interlayer insulation films H1 to H4. At this time, the respective gate electrodes G1 to G4 can be configured by the gate electrodes 7 and 8 of FIG. 1B.

In the semiconductor protrusion 2, diffusion layers F1 to F3 are formed corresponding to the height-direction positions of the interlayer insulation films H1 to H3, respectively. The semiconductor protrusion 2 may not include the diffusion layers F1 to F3.

The source layer 5 and the drain layer 6 are formed in the vertical direction of the semiconductor protrusion 2, whereby the gate electrodes G1 to G4 are stacked, so that the single semiconductor protrusion 2 can include plural transistors. Thus, the plural transistors can be integrated while suppressing increase of a layout area, and, at the same time, the reduction of the short channel effect and the increase of the current drive force can be simultaneously realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor protrusion formed on a semiconductor substrate;
a source/drain layer provided in a vertical direction of the semiconductor protrusion;
a gate electrode provided on a side surface of the semiconductor protrusion through a gate insulating film; and
a channel region provided on the side surface of the semiconductor protrusion, the potential height being different between the drain layer side and the source layer side.

2. The semiconductor device according to claim 1, wherein in the semiconductor protrusion, bandgaps on the drain layer side and the source layer side are different from each other.

3. The semiconductor device according to claim 2, wherein the semiconductor protrusion has a stacked structure including semiconductors having materials different from each other.

4. The semiconductor device according to claim 1, wherein in the gate insulating film, effective film thickness on the drain layer side and the source layer side are different from each other.

5. The semiconductor device according to claim 1, wherein in the gate electrode, work functions on the drain layer side and the source layer side are different from each other.

6. The semiconductor device according to claim 5, wherein the gate electrode has a stacked structure including W and Al.

7. The semiconductor device according to claim 5, wherein the gate electrode has a stacked structure including n-type polysilicon and p-type polysilicon.

8. The semiconductor device according to claim 5, wherein the gate electrode has a stacked structure including polysilicons with impurity concentrations different from each other.

9. The semiconductor device according to claim 5, wherein a plurality of the gate electrodes are stacked in the vertical direction of the semiconductor protrusion.

10. The semiconductor device according to claim 1, wherein a plurality of the semiconductor protrusions are stacked in the vertical direction through a diffusion layer.

11. The semiconductor device according to claim 1, wherein the semiconductor protrusion has a cylindrical shape.

12. The semiconductor device according to claim 11, wherein the gate electrode surrounds an outer periphery of the semiconductor protrusion.

13. The semiconductor device according to claim 1, wherein the drain layer is formed on an upper portion of the semiconductor protrusion, and the source layer is formed on a lower portion of the semiconductor protrusion.

14. The semiconductor device according to claim 13, wherein the source layer is formed on the entire lower portion of the semiconductor protrusion, and the semiconductor protrusion is separated from the semiconductor substrate through the source layer.

15. The semiconductor device according to claim 13, wherein the source layer is formed on a portion of the lower portion of the semiconductor protrusion, and the semiconductor protrusion is connected to the semiconductor substrate.

16. The semiconductor device according to claim 15, wherein the source layer is formed in a ring shape on a bottom surface of the semiconductor protrusion.

17. The semiconductor device according to claim 13, wherein the potential height in the channel region on the source layer side is higher than the drain layer side.

18. The semiconductor device according to claim 17, wherein impurity concentration in the channel region is set so that the channel region is completely depleted.

19. The semiconductor device according to claim 13, wherein the drain layer has a planar shape equal to the planar shape of the semiconductor protrusion.

20. The semiconductor device according to claim 19, wherein the source layer extends outward from the semiconductor protrusion.
